(19) United States
(12) Patent Application Publication
(10) Pub. No.: US 2024/0365441 A1
(43) Pub. Date: Oct. 31, 2024

(54) METHOD FOR CONTACTING AN ELECTRICALLY CONDUCTIVE PAPER STRUCTURE, COMPOSITE BODY AND USE

(71) Applicants: Giesecke +Devrient Currency Technology GmbH, Munchen (DE); Surteco GmbH, Butttenwiesen (DE)

(72) Inventors: Daniel Lenssen, Munchen (DE); Mario R. Keller, Munchen (DE); Stefan Schusser, Munchen (DE); Stephan Schunck, Munchen (DE); Martin Staiger, Munchen (DE); Michael Pfeifer, Munchen (DE); Marco Sauler, Munchen (DE)

(73) Assignees: Giesecke +Devrient Currency Technology GmbH, Munchen (DE); Surteco GmbH, Buttenwiesen (DE)

(21) Appl. No.: 18/682,614

(22) PCT Filed: Aug. 5, 2022
(86) PCT No.: PCT/EP2022/072136

§ 371 Date: Feb. 9, 2024

(30) Foreign Application Priority Data
Aug. 9, 2021 (DE) 10 2021 120 697.9

(51) Int. Cl. H05B 3/28; B32B 21/02; B32B 21/06

(52) U.S. Cl. CPC H05B 3/286; B32B 21/02; B32B 21/06; B32B 2307/202; B32B 2451/00; B32B 2479/00

(57) ABSTRACT

The invention relates to a composite body comprising a support plate having recesses, the support plate having an upper main surface and a lower main surface and an electrically conductive paper structure adjoining the upper main surface of the support plate, wherein the electrically conductive paper structure has at least one conductor track facing the upper main surface of the support plate, wherein conductor elements are introduced into the recesses of the support plate in such a way that the conductor elements are flush with the upper main surface of the support plate, wherein the conductor elements are in electrical contact with the at least one conductor track of the electrically conductive paper structure and wherein the conductor elements are contactable with a current source from the lower main surface of the support plate.

### CROSS-REFERENCE TO RELATED APPLICATIONS

This application is a national stage filing under 35 U.S.C. § 371 of International Patent Application No. PCT/EP2022/072136, filed Aug. 5, 2022, which claims the benefit of DE Application No. 10 2021 120 697.9 filed on Aug. 9, 2021, each of which is hereby incorporated by reference in its entirety.

### TECHNICAL FIELD

The invention relates to a method for contacting an electrically conductive paper structure. The invention further relates to a composite body and a use thereof.

Uniform, large-area heating of certain components is advantageous in many areas. For example, with regard to the cold walls in an airplane or a motor vehicle with possible furnishings, it is useful to introduce heating energy into the system via a fan in order to create a pleasant room climate. Heating energy is usually introduced, for example, in motor vehicles with possible furnishings via pipe systems that are operated electrically or with fossil fuels, require a great installation effort and, thus, are expensive. Heating large areas is difficult to achieve and condensation cannot be completely avoided.

In contrast, heated surfaces are a quick and usually more energy-saving alternative in terms of heat input. In addition, the heated surfaces inside a motor vehicle with possible furnishings help to prevent condensation. Heatable paper or paper-like materials are particularly suitable for this purpose, partly due to the on-board voltage used. It is known to make paper conductive by introducing conductive particles in the course of paper production, see e.g., U.S. Pat. No. 4,990,755 A, JP H-05 135 774 A and EP 1 063 716 A2. The current can be effectively coupled and thus distributed over the entire surface by a suitable application of conductive tracks, in particular busbars or conductor rails, for example by providing metallic strips, by printing, coating or vapor deposition with conductive materials or the like.

Conductive paper is particularly suitable for heating laminate panels because it can be impregnated and can be applied without major process changes during the production of decorative laminate panels. Other surface heating systems, such as those described in EP 3 691 408 A1 or EP 3 544 372 A1, can only be applied by additional process steps and remain visible. Usually, such a provision is only possible via additional components, which must be applied independently of the panel production. The disadvantages here are, of course, the costs and the additional work involved, but also visual limitations and possibly restrictions on moving parts. Printed, coated or vaporized conductor tracks are particularly advantageous in the case of heating with conductive paper because they do not represent a major barrier during impregnation and are no longer visible in the finished decorative panel. One challenge is to expose and contact the laminated conductive tracks again. The contacting should be as variable as possible with regard to the positioning of the contact points so that heating surfaces of different sizes can be easily manufactured. In addition, the connection issue must be taken into account, particularly with regard to moving parts, e.g., doors.

The present invention is based on the problem of overcoming the disadvantages of the prior art and providing an improved composite body and an improved method for contacting an electrically conductive paper structure. In particular, the composite body should be visually indistinguishable from the usual standard panels and should have an additional function, preferably heatability. The problem is solved by the feature combinations defined in the independent claims. Further embodiments of the invention are the subject of the dependent claims.

### SUMMARY OF THE INVENTION

1.(First aspect of the invention) A composite body comprising a support plate having recesses, the support plate having an upper main surface and a lower main surface and an electrically conductive paper structure adjoining the upper main surface of the support plate, wherein the electrically conductive paper structure has at least one conductor track facing the upper main surface of the support plate, wherein conductor elements are introduced into the recesses of the support plate in such a way that the conductor elements are flush with the upper main surface of the support plate, wherein the conductor elements are in electrical contact with the at least one conductor track of the electrically conductive paper structure and wherein the conductor elements are contactable with a current source from the lower main surface of the support plate.
(2) (Preferred embodiment) The composite body according to clause 1, wherein the electrically conductive paper structure has at least two conductor tracks facing the upper main surface of the support plate, wherein conductor elements are introduced into the recesses of the support plate in such a way that the conductor elements are flush with the upper main surface of the support plate, wherein the conductor elements are in electrical contact with the at least two conductor tracks of the electrically conductive paper structure and wherein the conductor elements are contactable with a current source from the lower main surface of the support plate.
(3) (Preferred embodiment) The composite body according to clause 1 or 2, wherein the recesses of the support plate are present in the form of bores and the conductor elements introduced into the bores are in the form of bolts, screws or countersunk rivets.
4. (Preferred embodiment) The composite body according to clause 1 or 2, wherein the recesses of the support plate are in the form of linear depressions, preferably milled lines, and wherein the conductor elements introduced into the linear depressions are present in the form of metal strips or metal rails, wherein the recesses present in the form of linear depressions optionally each have an additional bore which is adapted so that the respective conductor element introduced into the linear depression is contactable with a current source from the lower main surface of the support plate.
5. (Preferred embodiment) The composite body according to clause 1 or 2, wherein the recesses of the support plate are each in the form of a combination of a bore and a linear depression, preferably a milled line, wherein the bore is formed in the region of the linear depression and wherein the conductor elements are T-shaped in the form of a section introduced into the linear depression and at least one section introduced into the bore and arranged perpendicularly thereto.
6. (Preferred embodiment) The composite body according to any one of clauses 1 to 5, wherein the conductor elements are contacted with a current source from the lower main surface of the support plate using a plug connector or using a screw in connection with a cable lug, wherein the respective conductor element preferably has a bore or an internal thread.
7. (Preferred embodiment) The composite body according to any one of clauses 1 to 6, wherein the electrically conductive paper structure has a decorative layer on the side opposite to the support plate.
8. (Preferred embodiment) The composite body according to any one of clauses 1 to 7, wherein the support plate is a composite material, e.g., a chipboard, plywood, a medium-density (wood) fiber plate or MDF plate, a coarse chipboard or OSB plate, or a plastic-based, in particular thermoplastic, support plate.
9. (Preferred embodiment) The composite body according to any one of clauses 1 to 8, wherein the electrically conductive paper structure is based on cellulose-containing fibrous materials and electrically conductive fibers.
10. (Second aspect of the invention) A use of the composite body according to one any of clauses 1 to 9 as a heating element, as an element for electromagnetic shielding, as an element for supplying other electrical loads such as LEDs, as an element for discharging electrostatic charges or as an element for signal transmission or signal detection.
11. (Third aspect of the invention) A method of contacting an electrically conductive paper structure with a current source, comprising
the step of providing a support plate having recesses, the support plate having with an upper main surface and a lower main surface;
the step of introducing conductor elements into the recesses of the support plate in such a way that the conductor elements are flush with the upper main surface of the support plate,
the step of providing an electrically conductive paper structure which has at least one conductor track, preferably at least two conductor tracks, on a main surface;
the step of joining the support plate and the electrically conductive paper structure to form a composite body in such a way that the electrically conductive paper structure is adjoining the upper main surface of the support plate, wherein the conductor elements of the support plate are in electrical contact with the at least one conductor track, preferably with the at least two conductor tracks, of the electrically conductive paper structure and wherein the conductor elements of the support plate are contactable with a current source from the lower main surface of the support plate; and
the step of contacting the conductor elements of the support plate with a current source from the lower main surface of the support plate.
12. (Preferred embodiment) A method according to clause 11, wherein the composite body is defined according to any one of clauses 1 to 9.

### DETAILED DESCRIPTION OF THE PREFERRED EMBODIMENTS

Conventional surface heating systems can only be applied by complex process steps and remain visible, which leads to a high workload and high costs, to restrictions in moving parts and to visual limitations. The present invention is based on the use of an electrically conductive paper structure within a composite body for heating applications. Similar to decorative paper, the electrically conductive paper structure can be introduced without additional effort as part of the usual production of composite bodies, in particular composite plates. The major challenge is the reliable electrical contacting of a conductive layer embedded in an impregnating resin in particular. The present invention ensures simple, safe and durable electrical and mechanical contacting of the conductive layer in rigid and movable built-in parts. Compared to the state of the art, the use of the composite body according to the invention, for example in a motor vehicle with possible furnishings, results in a significant weight advantage and also a space saving due to the compact design.

In the course of manufacturing the composite body according to the invention, a support plate is provided with recesses. The recesses are in particular in the form of linear depressions, which are for example continuous or interrupted, preferably milled lines, and/or in the form of (in particular point-shaped) bores, drilled holes, through-holes or perforations. The recesses are filled with conductor elements, i.e., electrically conductive elements or contact elements, so that the conductor elements are flush with the support plate on the side on which the electrically conductive paper structure is applied. The conductor elements can be in particular in the form of metal bands, metal rails, metal strips, metal bolts, screws or contact rivets or countersunk rivets. With regard to the metal, copper or zinc are preferred, with copper being particularly preferred. Conveniently, at least two parallel conductor tracks are applied to the electrically conductive paper structure, which distribute the current along the conductor elements. The conductor elements are positioned in such a way that they are in electrical contact with the conductor tracks of the electrically conductive paper structure and are also contactable in the final composite body. According to the present invention, it is in principle sufficient if only one conductor track is applied onto the electrically conductive paper structure. In the following description, the invention is described with reference to particular embodiments in which at least two parallel conductive tracks are applied onto the electrically conductive paper structure.

As can be seen from the attached FIG. 1, the support plate is suitably prepared for receiving the conductor elements by drilling and/or milling in the region of the side that will later come into contact with the electrically conductive paper structure. The number and size of the recesses, in particular drilled holes and/or milling lines, is advantageously selected to the maximum extent possible in such a way that the stability of the support plate is maintained. The conductor elements, e.g. (copper) countersunk rivets, bolts or (thread-cutting) screws, are introduced into the recesses with precise fit. The conductor element must be flush with the support plate. The recesses, e.g. bores, extend precisely parallel to the at least two conductor tracks of the electrically conductive paper structure on the side of the support plate to be coated with the electrically conductive paper structure.

The electrically conductive paper structure provided with the conductor tracks, e.g. metal strips such as copper or zinc strips, is applied to the support plate provided with the conductive elements, e.g. by lining, laminating, gluing or pressing, so that the conductive tracks and the conductive elements are in permanent current-carrying contact with each other. The decorative layer is then, or possibly simultaneously, applied. A decorative paper or a decorative (finish) film is suitable as a decorative layer, whereby the decorative layer may be impregnated, printed or painted. With regard to the support plate, a composite material, e.g. a chipboard, plywood, a medium-density (wood) fiber plate or MDF plate, a coarse chipboard or OSB plate, or a plastic-based, in particular thermoplastic, support plate is suitable.

If the recesses in the support plate are in the form of bores (variant 1), (copper) countersunk rivets, which are introduced into the drilled holes in the support plate, are preferably suitable as conductor elements. The respective (copper) countersunk rivet can be provided with a thread or a drilled hole on the back side. Suitably, the diameter of the drilled hole of the support plate is greater than or equal to the pin diameter of the (copper) countersunk rivet. Furthermore, the length of the (copper) countersunk rivet is advantageously smaller than the thickness of the support plate. The respective bore can be produced, for example, by drilling, but also by laser perforation or by cutting, e.g., by laser cutting.

If the recesses in the support plate are in the form of linear depressions, e.g., milling lines (variant 2), the composite body is manufactured in the same way as described above. Accordingly, the support plate is prepared to receive the conductor elements, e.g. by milling. The milling line is conveniently introduced deep into the material so as to maintain the stability of the support plate. The conductor elements, e.g. metal rails, metal strips such as copper strips or the like, are introduced precisely into the milling lines or grooves. The respective conductor element must be flush with the support plate. On the side of the support plate to be coated with the electrically conductive paper structure, the milling lines extend precisely parallel to the at least two conductor tracks of the electrically conductive paper structure. The conductive elements, in particular metal strips such as copper strips or the like, are suitably sufficiently thick and sufficiently mechanically stable so that the support plate is not damaged during the subsequent steps in the course of lining or pressing. The electrically conductive paper structure provided with the conductor tracks, e.g. copper strips, is applied onto the support plate provided with the conductor elements, e.g. by lining, laminating, gluing or pressing, so that the conductor tracks and the conductor elements are in permanent current-carrying contact with each other. The decorative layer is then applied, or optionally at the same time. The conductor elements are then exposed, with a bore on the rear side preferably being drilled at any locations parallel to the respective milling line. In the case of a metal rail as the conductive element, the metal rail acts as a stop point and prevents drilling through or visible defects on the decorative side.

An alternative design is based on a combination of a linear depression, in particular a milling line, and a bore (variant 3). Here, the support plate is prepared for receiving the conductor elements both by providing a linear depression, in particular a milling line, and by providing bores. The linear depressions extend deep into the material so as to ensure that the support plate remains stable. In addition, the maximum number and size of the bores are suitably chosen so as to ensure the stability of the support plate and the conductor element. The conductor elements, e.g. metal rails such as copper rails, are each introduced into a groove (also referred to as an elongated depression or elongated notch) at defined intervals. The metal rail, in particular a copper rail, is first fitted with threaded welding studs, for example. The support plate has bores that are arranged to match the threaded welding studs. The diameter of the bores is preferably larger than the nominal diameter of the studs and the depth of the bores is preferably longer than the length of the studs in order to avoid manufacturing tolerances and material stresses. The conductor element must be flush with the support plate. The linear depressions, in particular milling lines, on the side of the support plate to be coated with the electrically conductive paper structure extend precisely parallel to the conductor tracks of the electrically conductive paper structure to be applied in a further process step. The electrically conductive paper structure provided with the conductive tracks, e.g. copper strips, is applied onto the support plate provided with the conductive elements, e.g. by lining, laminating, gluing or pressing, so that the conductive tracks and the conductive elements are in electrical contact with each other. The decorative layer is then, or optionally simultaneously, applied.

In all three variants, the conductor elements are connected to a power source using, for example, plug connectors such as banana plugs or similar plug connectors, which may also be self-locking, preferably in connection with (copper) countersunk rivets as conductor elements. In the case of a (copper) countersunk rivet with an internal thread as the conductor element, contacting by using a cylinder head screw or comparable screw types is appropriate. If the conductor element is provided by a screw with a bore or by a threaded weld stud, the contact can be made by using a thread-forming screw. Optionally, all types of contact can be made in connection with a cable lug and washers.

Another option for rear side contacting is based on a bond between the (copper) countersunk rivet and the rear side connection cable using a conductive adhesive or a soldered connection with suitable soldering compound.

The advantages achieved on the basis of the plane-parallel surface of the support plate, which is flush with the conductor element, are the low additional effort required for installation, the low visual visibility of additional components and the possibility of connecting several elements in series, resulting in reduced wiring effort. Compared to the state of the art, this also results in weight savings. Furthermore, the use of non-fossil fuels for heating is possible.

Other special advantages of variant 1 described above are:
the almost unrestricted workability of the composite body, in particular the ability to cut it to size;
the pre-manufactured contacting, so to speak, and thus the immediate electrical, current-carrying contactability, i.e., the access to the rear side is already available so that no additional drilling is necessary;
avoiding the risk of perforation of the decorative layer, e.g. through careless drilling;
the high degree of freedom with regard to the use of alternative designs, e.g. elements with windings, soldered connections or adhesive connections.

Special advantages of variant 2 described above are furthermore:
the increased current-carrying capacity in view of the increased cross-section, because current can be transported partially or possibly primarily via metal rails or metal strips; this makes it possible to provide even a smaller conductor track layer on the electrically conductive paper structure;
the metal rail or metal strip can be contacted from any location, e.g. from behind (e.g. by simply drilling a hole up to the metal rail).

Special advantages of variant 3 described above are furthermore:
the pre-manufactured contacting, so to speak, and thus immediate electrical, current-carrying contactability, i.e., the access to the rear side is already available and therefore no additional drilling is necessary;
the increased current-carrying capacity in view of the increased cross-section, because current can be transported partially or possibly primarily via metal rails or metal strips; this means that even a thinner conductor track layer can be provided on the electrically conductive paper structure;
If conductive elements are provided with bores (possibly with internal threads), there is an additional advantage in that there is no risk of perforation of the decorative layer, e.g. due to careless drilling;
If conductive elements are provided with threaded welding studs (with internal or external threads), there is also no risk of perforation or damage to the decorative layer, e.g. due to too long screws.

The electrically conductive paper structure can be produced using conventional papermaking methods, in particular inclined wire, fourdrinier and cylinder mould technology. In this way, it is basically possible to process varying fiber compositions. It is useful to add conductive, metallic short-cut fibers to cellulose-containing or alternatively plastic-based fibers. The metallic short-cut fibers typically have a fiber length in the range of 3 to 12 mm. The quantity in which the conductive, metallic short-cut fibers are added is suitably selected so that sufficient fiber-to-fiber contacts are provided and thus a suitable electrical current flow is ensured. The electrically conductive paper structure may contain other natural and/or synthetic fibers, optionally chemical additives and residual moisture. Furthermore, the electrical conductivity can be achieved not only by conductive, metallic fibers, in particular metallic short-cut fibers, but also by adding carbon fibers, carbon particles or carbon nanotubes. Alternatively, conductivity can be achieved via a conductive surface coating. Furthermore, the term (paper) structure also includes other fabrics, fleece materials or the like, in particular foil-based conductive materials.

### BRIEF DESCRIPTION OF THE DRAWINGS

Further embodiments and advantages of the invention are explained below with reference to the figures, which have not been reproduced true to scale and proportion in order to increase clarity.

FIGS. 1 and 2 a first exemplary embodiment of an inventive composite body;

FIGS. 3 and 4 a second exemplary embodiment of an inventive composite body;

FIGS. 5 and 6 a third exemplary embodiment of an inventive composite body;

FIGS. 7 and 8 a fourth exemplary embodiment of an inventive composite body;

FIGS. 9 and 10 a fifth exemplary embodiment of an inventive composite body;

FIGS. 11 and 12 a sixth exemplary embodiment of an inventive composite body;

FIG. 13 a seventh exemplary embodiment of an inventive composite body; and

FIG. 14 an eighth exemplary example of an inventive composite body.

### DETAILED DESCRIPTION

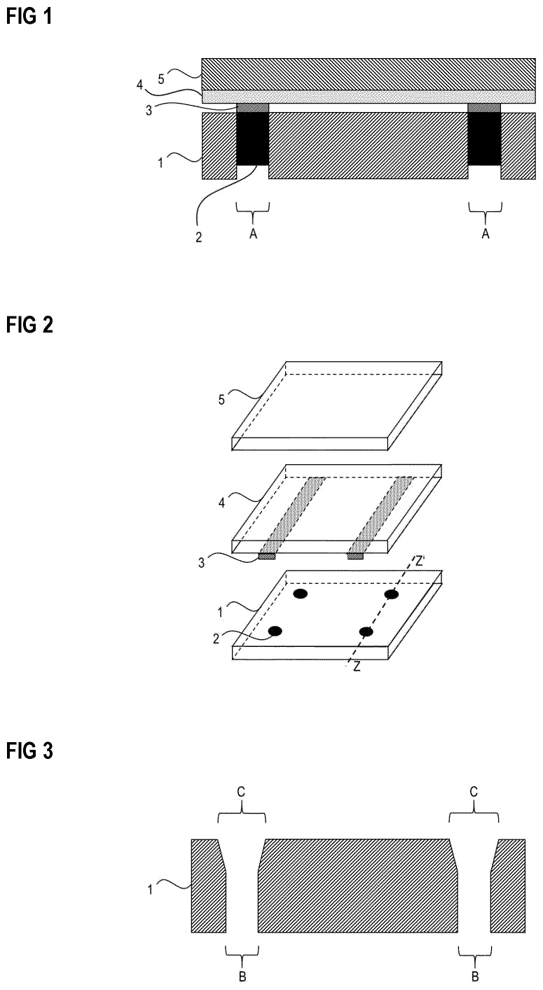

FIGS. 1 and 2 illustrate a first exemplary embodiment of an inventive composite body. According to FIG. 1, a support plate 1, in this example a chipboard, is first provided. The support plate is provided with continuous, circular bores 2, each of which has the diameter A. The bores 2 are then provided with conductor elements 2, in the example electrically conductive bolts, wherein the conductor elements 2 are flush with the support plate 1 on their upper side and can be contacted on their lower side in the final composite body. In the next step, an electrically conductive paper structure 4 is laminated on, which is provided with conductor tracks 3, e.g. copper strips. The lamination is carried out in such a way that the conductor tracks 3 and the conductor elements 2 are in electrical contact with each other. A decorative layer 5, in this example a decorative paper, is also provided.

FIG. 2 shows an angled view of the composite body shown in FIG. 1. The cross-sectional view shown in FIG. 1 extends along the dashed line Z-Z′ shown in FIG. 2.

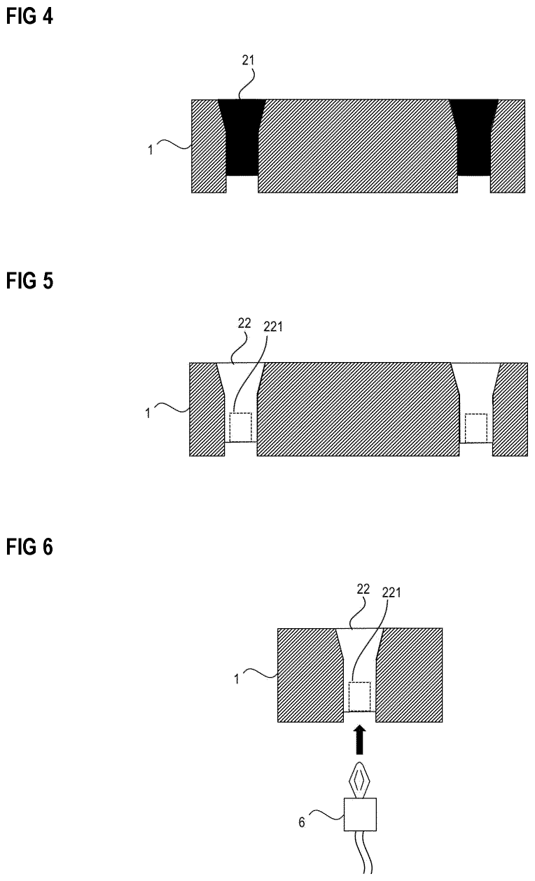

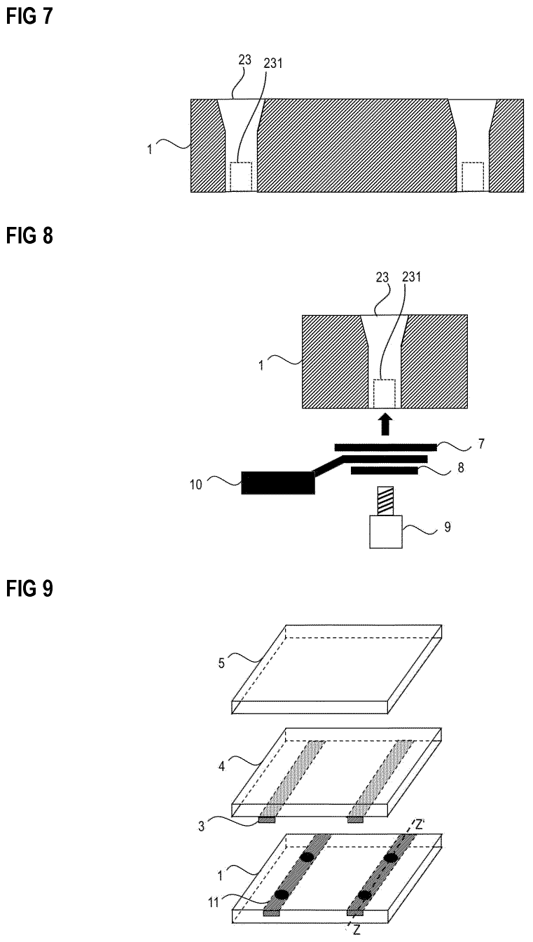

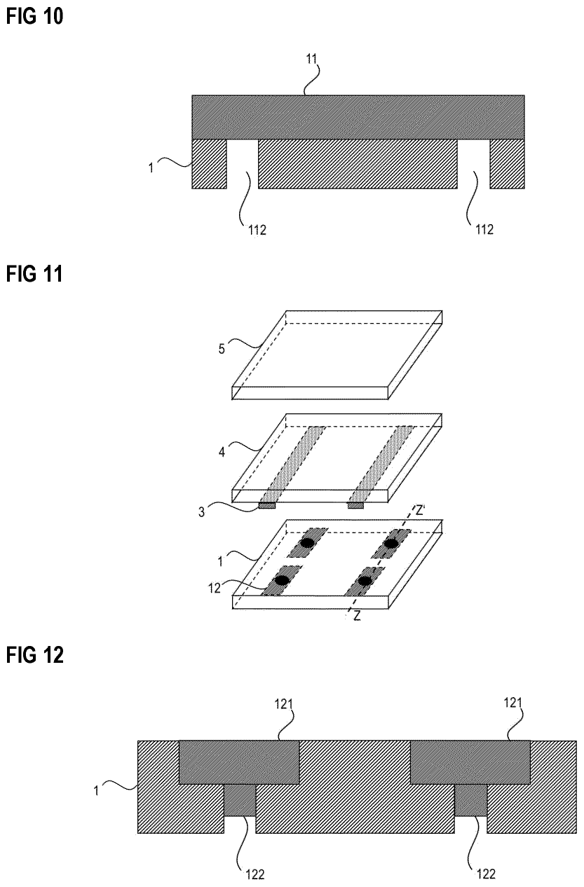

FIGS. 3 and 4 illustrate a second exemplary embodiment of an inventive composite body, which is based on the first exemplary embodiment. FIGS. 3 and 4 each show a cross-sectional view along the dashed line Z-Z′ shown in FIG. 2. In contrast to the first exemplary embodiment shown in FIGS. 1 and 2, in the second exemplary embodiment, through-bores are drilled in the support plate 1 in such a way that the bores are suitable for countersunk rivets, in particular countersunk rivets in accordance with DIN 661. According to FIG. 3, the through-bores have a head diameter C and a shaft diameter B. FIG. 4 illustrates the support plate 1 provided with (copper) countersunk rivets 21 as conductive elements. The increased head diameter C of the (copper) countersunk rivet 21 ensures simplified assembly to ensure a flush fit of the (copper) countersunk rivet 21 with the support plate 1.

FIGS. 5 and 6 illustrate a third exemplary embodiment of an inventive composite body, which is based on the second exemplary embodiment. FIGS. 5 and 6 each show a cross-sectional view along the dashed line Z-Z′ shown in FIG. 2. In the present case, (copper) countersunk rivets are also used as conductor elements. Compared to the second exemplary embodiment, the (copper) countersunk rivets 22 introduced into the support plate 1 have a bore 221 (see FIG. 5). According to FIG. 6, the bore 221 is used for improved rear-side contacting with, for example, a plug connector 6, in the present example a banana plug.

FIGS. 7 and 8 illustrate a fourth exemplary embodiment of a composite body, which is based on the first exemplary embodiment. Also in the present case, (copper) countersunk rivets 23 are used as conductor elements. In the present exemplary embodiment, the length of the (copper) countersunk rivets 23 is identical to the thickness of the support plate 1. In addition, the (copper) countersunk rivets 23 have an internal thread 231 (see FIG. 7). According to FIG. 7, the internal thread 231 of the countersunk rivet 23 serves as rear side contacting using a threaded screw 9. In the present example, the electrical connection is made according to FIG. 8 using a cable lug 10 and using of washers 7 and 8, the thickness, outer and inner diameter of which are adapted to the mechanical and electrical conditions.

Each of the first to fourth exemplary embodiment is encompassed by variant 1 explained in the description above, according to which bores introduced into the support plate in a point-shaped manner serve to accommodate cylindrical conductor elements such as bolts or countersunk rivets.

FIGS. 9 and 10 illustrate a fifth exemplary embodiment of an inventive composite body, which is encompassed by variant 2 explained in the above description. Here, a linear depression introduced into the support plate 1, in particular a milled line, serves to accommodate a metal strip (in particular a copper strip) or a metal rail (in particular a copper rail) as a conductor element 11 (see FIG. 9). FIG. 10 shows a cross-sectional view of the support plate 1 along the dashed line Z-Z′ shown in FIG. 9. FIG. 10 shows that the lower side of the conductor element 11 is exposed from below in order to provide contact, e.g. by means of rear side bores 112 drilled precisely at any locations parallel to the linear depression.

The conductor elements 11 shown in FIGS. 9 and 10 are flush with the support plate 1 on their upper side and can be contacted electrically and with current-carrying capacity on their lower side in the final composite body. As in the previous exemplary embodiments, the next steps involve laminating an electrically conductive paper structure 4, which is provided with conductor tracks 3, e.g. copper strips. The lamination is carried out in such a way that the conductor tracks 3 and the conductor elements 11 are in contact with each other. Finally, a decorative layer 5, in this example a decorative paper, is applied.

FIGS. 11 and 12 illustrate a sixth exemplary embodiment of an inventive composite body, which is encompassed by variant 3 explained in the above description. According to FIG. 11, the support plate 1 is prepared for receiving T-shaped conductor elements 12 both by milling and by providing bores. FIG. 12 shows a cross-sectional view taken along the dashed line Z-Z′ of FIG. 11. The T-shaped conductor elements have a rail-shaped section 121 and a cylindrical section 122 perpendicular thereto. Suitably, threaded welding studs are welded onto the metal rails to produce the conductive elements. The support plate 1 has bores that are arranged to match the threaded welding studs 122. The diameter of the bores is suitably larger than the nominal diameter of the studs 122 and the depth of the bores is advantageously longer than the length of the studs 122 in order to prevent manufacturing tolerances and material stresses. The conductor element 12 is flush with the support plate 1. The linear depressions, in particular milling lines, extend on the side of the support plate 1 to be coated with the electrically conductive paper structure 4 precisely parallel to the conductor tracks 3 of the electrically conductive paper structure 4 to be applied in a further process step. The electrically conductive paper structure 4 provided with the conductive tracks 3, e.g. copper strips, is applied to the support plate 1 provided with the conductive elements 12, for example by lamination, so that the conductive tracks 3 and the conductive elements 12 are in electrical, current-carrying contact with each other. The decorative layer 5 is then applied.

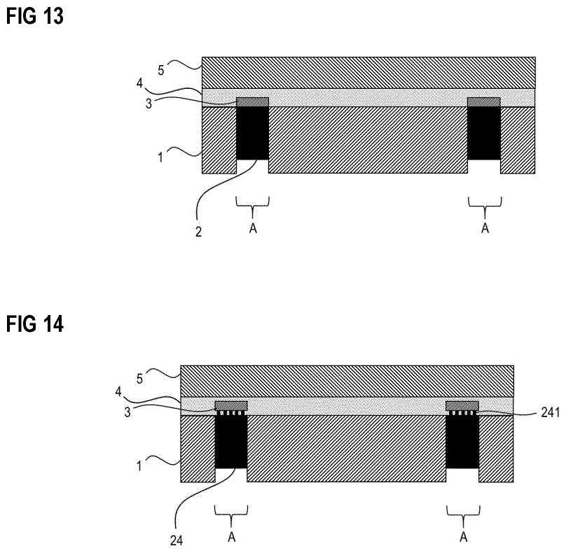

FIG. 13 illustrates a seventh exemplary embodiment of an inventive composite body, which is based on the first exemplary embodiment described with reference to FIGS. 1 and 2. According to FIG. 13, the electrically conductive paper structure 4 is provided with conductor tracks 3, e.g. copper strips, in such a way that the conductor tracks 3 are embedded in the paper structure 4, wherein the embedding is carried out in such a way that the conductor tracks 3 are freely accessible from one side.

FIG. 14 illustrates an eighth exemplary embodiment of an inventive composite body, which is based on the first exemplary embodiment described with reference to FIGS. 1 and 2. According to FIG. 14, the electrically conductive paper structure 4 is provided with conductor tracks 3, e.g. copper strips, in such a way that the conductor tracks 3 are completely embedded in the paper structure 4. The conductor elements 24 have needle-shaped projections 241 on their upper side, via which the conductor tracks 3 and the conductor elements 24 are in electrical contact with each other.

According to a ninth exemplary embodiment not shown in the drawings, which represents an intermediate position between the seventh and eighth exemplary embodiments illustrated in FIGS. 13 and 14, the embedding of the conductor track 3 in the paper structure 4 is carried out in such a way that the conductor track 3 is completely embedded in certain regions of the electrically conductive paper structure 4 (see the embedding shown in FIG. 14) and is embedded in certain regions of the electrically conductive paper structure 4 in such a way that the conductor track 3 is freely accessible from one side and is electrically contactable with the conductor element 2 (see the embedding shown in FIG. 13). The partially exposed conductor track 3 described in the ninth exemplary embodiment is similar to a window security thread known in the technical field of banknotes, which is completely embedded in the paper in certain regions and protrudes from the surface of the paper in certain window regions. For example, FIG. 1 of EP 3 034 315 A1 shows a banknote with a window security thread. The manufacturing can be carried out using a cylinder mould paper machine, for example. Alternatively, the partially exposed regions can be produced, for example, by removing the paper in the window regions.

In the above embodiments, two conductive tracks 3 are applied to the electrically conductive paper structure 4. According to the present invention, it is generally sufficient if only one conductor track 3 is applied to the electrically conductive paper structure 4.

Furthermore, the preceding embodiments can be combined with each other. For example, the conductive element 11 shown in FIG. 10 can be provided in the regions 112 with the threaded welding studs 122 shown in FIG. 12 in order to form in this way a conductive element in the form of two interconnected T-shaped conductive elements.

1. A composite body comprising a support plate having recesses, the support plate having an upper main surface and a lower main surface and an electrically conductive paper structure adjoining the upper main surface of the support plate, wherein the electrically conductive paper structure has at least one conductor track facing the upper main surface of the support plate, wherein conductor elements are introduced into the recesses of the support plate in such a way that the conductor elements are flush with the upper main surface of the support plate, wherein the conductor elements are in electrical contact with the at least one conductor track of the electrically conductive paper structure and wherein the conductor elements are contactable with a current source from the lower main surface of the support plate.

2. The composite body according to claim 1, wherein the electrically conductive paper structure has at least two conductor tracks facing the upper main surface of the support plate, wherein conductor elements are introduced into the recesses of the support plate in such a way that the conductor elements are flush with the upper main surface of the support plate, wherein the conductor elements are in electrical contact with the at least two conductor tracks of the electrically conductive paper structure and wherein the conductor elements are contactable with a current source from the lower main surface of the support plate.

3. The composite body according to claim 1, wherein the recesses of the support plate are present in the form of bores and wherein the conductor elements introduced into the bores are present in the form of bolts, screws or countersunk rivets.

4. The composite body according to claim 1, wherein the recesses of the support plate are present in the form of linear depressions, preferably milling lines, and wherein the conductor elements introduced into the linear depressions are present in the form of metal strips or metal rails, wherein the recesses present in the form of linear depressions optionally each have an additional bore which is adapted so that the respective conductor element introduced into the linear depression is contactable with a current source from the lower main surface of the support plate.

5. The composite body according to claim 1, wherein the recesses of the support plate are each in the form of a combination of a bore and a linear depression, preferably a milled line, wherein the bore is formed in the region of the linear depression and wherein the conductor elements are T-shaped in the form of a section introduced into the linear depression and at least one section introduced into the bore and arranged perpendicularly thereto.

6. The composite body according to claim 1, wherein the conductor elements are contacted with a current source from the lower main surface of the support plate using a plug connector or using a screw in connection with a cable lug, wherein the respective conductor element preferably has a bore or an internal thread.

7. The composite body according to claim 1, wherein the electrically conductive paper structure has a decorative layer on the side opposite to the support plate.

8. The composite body according to claim 1, wherein the support plate is a composite material, e.g., a chipboard, plywood, a medium-density (wood) fiber plate or MDF plate, a coarse chipboard or OSB plate, or a plastic-based, in particular thermoplastic, support plate.

9. The composite body according to claim 1, wherein the electrically conductive paper structure is based on cellulose-containing fibrous materials and electrically conductive fibers.

10. A use of the composite body according to claim 1 as a heating element, as an element for electromagnetic shielding, as an element for supplying other electrical loads such as LEDs, as an element for discharging electrostatic charges or as an element for signal transmission or signal detection.

11. A method of contacting an electrically conductive paper structure with a current source, comprising
the step of providing a support plate having recesses, wherein the support plate has an upper main surface and a lower main surface;
the step of introducing conductor elements into the recesses of the support plate in such a way that the conductor elements are flush with the upper main surface of the support plate,
the step of providing an electrically conductive paper structure which has at least one conductor track, preferably at least two conductor tracks, on a main surface;
the step of joining the support plate and the electrically conductive paper structure to form a composite body in such a way that the electrically conductive paper structure is adjoining the upper main surface of the support plate, wherein the conductor elements of the support plate are in electrical contact with the at least one conductor track, preferably with the at least two conductor tracks, of the electrically conductive paper structure, and wherein the conductor elements of the support plate are contactable with a current source from the lower main surface of the support plate; and
the step of contacting the conductor elements of the support plate with a current source from the lower main surface of the support plate.

12. (canceled)
